(19) United States
(12) Patent Application Publication
(10) Pub. No.: US 2008/0042270 A1
(43) Pub. Date: Feb. 21, 2008

(54) System and method for reducing stress-related damage to ball grid array assembly

(76) Inventors: Daryl Carvis Cromer, Cary, NC (US); Seita Horikoshi, Zama-shi (JP); Tadashi Kosuga, Shiga-Ken (JP); Howard Jeffrey Locker, Cary, NC (US); Tin-Lup Wong, Chapel Hill, NC (US); Kenshin Yonemochi, Komakura-shi (JP)

Correspondence Address: ROGITZ & ASSOCIATES, 750 B STREET, SUITE 3120, SAN DIEGO, CA, 92101, US

(21) Appl. No.: 11/505,704

(22) Filed: Aug. 17, 2006

(51) Int. Cl. H01L 23/48; H01L 21/44

(52) U.S. Cl. 257/737; 257/E23.069; 438/613

(57) ABSTRACT

A ball grid array (BGA) includes straight pins at the corners and if desired along the edges of the array that are engaged with a PCB to reduce stress on the solder balls. The pins can be on the chip substrate of the BGA or on a separate frame that is glued to the chip substrate.

### I. FIELD OF THE INVENTION

The present invention relates generally to ball grid array (BGA) assemblies.

### II. BACKGROUND OF THE INVENTION

Ball Grid Assembly (BGA) packages are widely used in cell phone and mobile computers to hold integrated circuit chips onto printed circuit boards (PCB) by means of an array of small solder balls that are disposed on the chip substrate and heated when the chip is placed onto the PCB to effect a solder connection. BGA technology is evolving because continued technology shifts are allowing denser and smaller packaging and product designs. At the same time, changes in government standards are forcing shifts in technologies (e.g., lead free solder) that are reducing the parts resistance to repeated stress cycles (bending, g-forces, vibration, etc). In addition, as product design moves to complex mobile devices, solutions are required to isolate the motherboard and other critical parts in the systems (circuit boards, drives, etc) from these stress factors.

As recognized herein, as BGA packages become smaller they become more susceptible to solder joint damage due to overstress. The damage can be caused by so-called “ECAT” processes, manufacturing and assembly, and customer environment. Minute cracks that develop are not easily detected and require employing expensive electron microscope and destructive tests.

Unfortunately, as understood herein many current chipsets including graphics chips use BGA packages solely based on electronic pin-out requirements and ignore the needs for structure integrity and reliability in use for mobile devices, which can be subject to considerable shock and stress during transport. Package design with stiffer substrate materials, lead-free solder, smaller BGA solder pitch (0.8 mm to 1.0 mm) and 1200+ solder balls reduces maximum allowable strain or deformation to the printed circuit board, or PCB, hence it is easier to cause overstress to BGA solder joints owing to the direction that the technology is taking.

### SUMMARY OF THE INVENTION

A ball grid array (BGA) assembly includes a BGA that has an integrated circuit chip, a chip substrate supporting the chip, and plural solder balls on the substrate. A printed circuit board (PCB) is provided to which the balls are soldered to hold the BGA onto the PCB. The BGA also includes plural straight pins that are engaged with the PCB.

In one implementation, a pin extends substantially from each corner of the BGA toward the PCB. Pins may also be disposed along each edge of the BGA. The pins can be attached to the chip substrate itself or they can be attached to a frame that is engaged with the chip substrate.

Several methods for engaging the pins with the PCB are disclosed. In one method, the pins extend through respective holes in the PCB and are soldered to the PCB. In another method, the pins are surface soldered to the surface of the PCB facing the BGA. In still another method, the pins extend through respective holes in the PCB and are engaged with respective threaded fasteners on the surface of the PCB facing away from the BGA to pre-stress the package.

In another aspect, a ball grid array (BGA) includes an integrated circuit chip, a chip substrate supporting the chip, and plural solder balls on the substrate and positionable against a printed circuit board (PCB) to which the balls can be soldered to hold the BGA onto the PCB. Additionally, plural pins extend away from the chip substrate and can be engaged with the PCB.

In yet another aspect, a method for mounting a ball grid array (BGA) onto a printed circuit board (PCB) includes soldering plural balls on the BGA to the PCB, and engaging plural pins extending from the BGA with the PCB.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is an exploded perspective view of a BGA with PCB, showing stress relief pins attached to the chip substrate of the BGA, with portions of the pins shown in phantom;

FIG. 2 is an exploded perspective view of a BGA with frame, showing stress relief pins attached to the frame, with portions of the pins shown in phantom;

FIG. 3 is a perspective view of the frame engaged with the BGA of FIG. 2, with portions of the pins shown in phantom; and

FIG. 4 is a side elevation view of the PCB 14 with pin support structure (either the chip substrate of FIG. 1 or the frame of FIGS. 2 and 3), schematically showing various methods for mounting the pins to the PCB.

### DETAILED DESCRIPTION OF THE PREFERRED EMBODIMENT

FIG. 1 illustrates a ball grid array (BGA), generally labeled 2. The BGA includes a circuit chip 4 supported on a substrate 6. Plural solder balls 8 are arranged on the underside of the substrate 6. The BGA 2 may be attached a printed circuit board 14, or PCB, by soldering the balls 8 onto the PCB 14 by means of heat. By “balls” is meant both spherical balls proper as well as cylindrical solder columns. As recognized herein, stress may build up on the soldered balls 8 between the BGA 2 and the PCB 14 and can be lessened by use of the below-described pins.

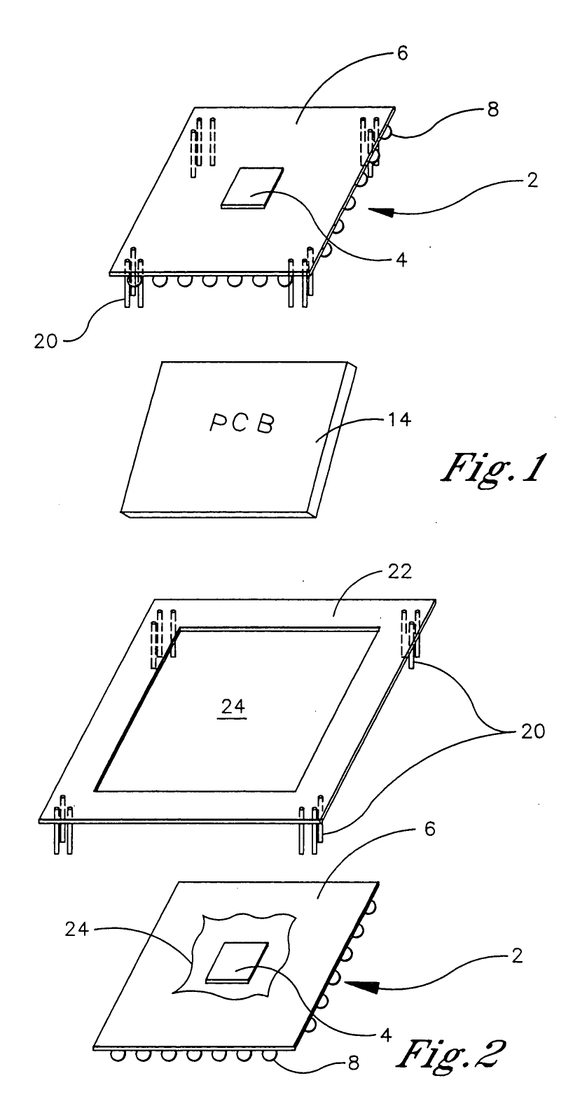

With greater specificity, pins 20 are attached to either the corners, as shown in FIG. 1, and/or to the edges of the substrate 6, which supports the circuit chip 4. The pins 20 may alternatively be attached to a preferably hollow parallelepiped-shaped frame 22 that can be glued to the substrate 6 of the BGA 2 as shown in FIG. 2. A glue is indicated at 24 in FIG. 2. The frame 22 is configured to border the substrate 6 of the BGA 2 under equal margins and can if desired slightly overlap the edges of the BGA 2, as shown in FIG. 3, with a window 24 being formed centrally in the frame in non-limiting implementations to expose the chip 4. In either the embodiment of FIG. 1 or the frame embodiment of FIGS. 2 and 3, the pins 20 are shown extending down toward the PCB 14 from the corners of the chip substrate 6/frame 22, it being understood that pins 20 can also be provided along the edges of the substrate 6/frame 22.

In any case, the pins 20 are elongated and are straight compared to the balls 8. The pins 20 can be made of solder material so that the pins 20 can be soldered to the PCB 14 in similar manner to the balls 8, thereby relieving nearby balls 8 of stress.

The BGA 2 in FIG. 1 may be considered to be a “BGA”, with the BGA 2 with frame 22 of FIGS. 2 and 3 also establishing a “BGA”.

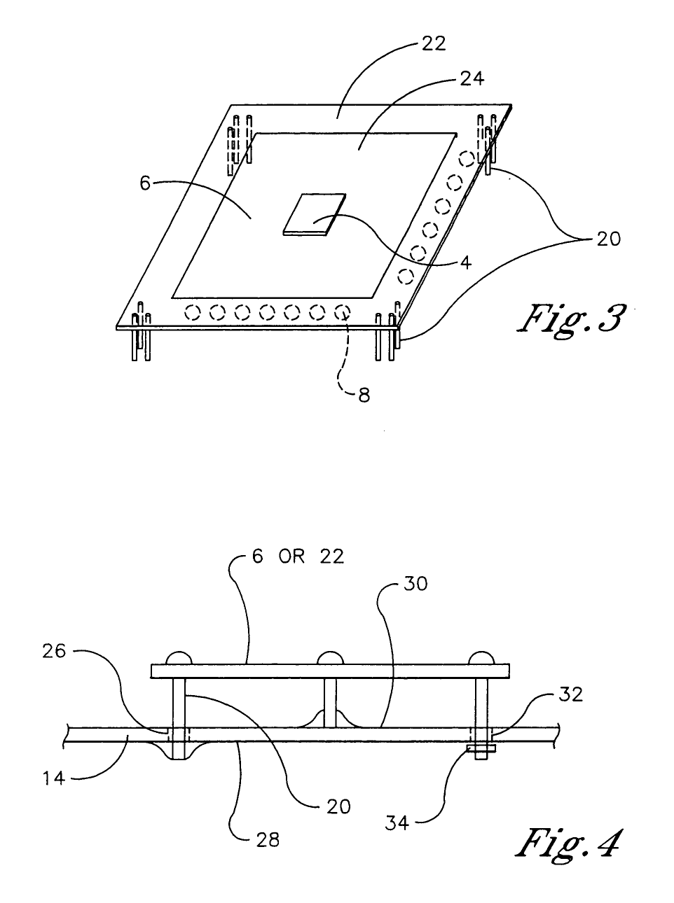

FIG. 4 shows various ways in which the pins 20 can be engaged with the PCB 14. As the left-moist pin 20 shown in FIG. 4 illustrates, a pin 20 can extend through a respective hole 26 in the PCB and be soldered to the PCB on the surface 28 of the PCB facing away from the BGA 2 in a so-called “pin-through-hole” method.

Alternatively, as shown by the middle pin in FIG. 4, the pins 20 can be soldered to the surface 30 of the PCB 14 that faces the BGA 2 in a so-called “surface solder” method.

Yet again, as shown by the right-most pin in FIG. 4, a pin 20 can extend through a respective hole 32 in the PCB from the surface 30 of the PCB 14 to the opposite surface 28 and be engaged with a threaded fastener 34 on the opposite surface 28 of the PCB. In this latter embodiment the pin 20 may be threaded. In any case, in non-limiting implementations the fastener 34 can be tightened as desired to pre-load the assembly to minimize the typically residual BGA package strain (which can range from two hundred micro-strains to six hundred micro-strains). Moreover, the fastener 34 at one corner of the package might be tightened to a different torque than that used to tighten the fastener at another corner as necessary to alleviate stress from warpage.

Only one of the three methods shown in FIG. 4 for engaging the pins 20 with the PCB 14 may be used in any given package, or any two or even all three may be used in a single package.

While the particular SYSTEM AND METHOD FOR REDUCING STRESS-RELATED DAMAGE TO BALL GRID ARRAY ASSEMBLY is herein shown and described in detail, it is to be understood that the subject matter which is encompassed by the present invention is limited only by the claims.

What is claimed is:

1. A ball grid array (BGA) assembly comprising:
a BGA including an integrated circuit chip, a chip substrate supporting the chip, and plural solder balls on the substrate; and
a printed circuit board (PCB) to which the balls are soldered to hold the BGA onto the PCB, wherein
the BGA also includes plural straight pins engaged with the PCB.

2. The BGA assembly of claim 1, wherein the chip substrate defines at least three corners, and at least one pin extends substantially from each corner toward the PCB.

3. The BGA assembly of claim 2, wherein the chip substrate defines at least three edges, and pins are disposed along each edge.

4. The BGA of claim 1, wherein the pins extend through respective holes in the PCB and are soldered to the PCB.

5. The BGA of claim 1, wherein the pins extend through respective holes in the PCB from a BGA surface of the PCB to an opposite surface of the PCB, at least one pin being engaged with a threaded fastener on the opposite surface of the PCB.

6. The BGA of claim 1, wherein the pins face a BGA surface of the PCB, the pins being soldered to the BGA surface.

7. The BGA of claim 1, wherein the pins are attached to the chip substrate.

8. The BGA of claim 1, wherein the pins are attached to a frame, the frame being engaged with the chip substrate.

9. A ball grid array (BGA) comprising:
an integrated circuit chip;
a chip substrate supporting the chip;
plural solder balls on the substrate and positionable against a printed circuit board (PCB) to which the balls can be soldered to hold the BGA onto the PCB; and
plural pins extending away from the chip substrate and engageable with the PCB.

10. The BGA of claim 9, wherein the chip substrate defines at least three corners, and at least one pin extends substantially from each corner.

11. The BGA of claim 10, wherein the chip substrate defines at least three edges, and pins are arranged along each edge.

12. The BGA of claim 9, wherein the pins are attached to the chip substrate.

13. The BGA of claim 9, wherein the pins are attached to a frame, the frame being engaged with the chip substrate.

14. A method for mounting a ball grid array (BGA) onto a printed circuit board (PCB), comprising:
soldering plural balls on the BGA to the PCB; and
engaging plural pins extending from the BGA with the PCB.

15. The method of claim 14, wherein the pins are arranged to alleviate stress on at least some balls.

16. The method of claim 14, wherein the pins are connected to a chip substrate of the BGA.

17. The method of claim 14, wherein the pins are connected to a frame and the frame is engaged with a chip substrate of the BGA.

18. The method of claim 14, comprising disposing the pins through respective holes in the PCB and soldering the pins to the PCB.

19. The method of claim 14, comprising disposing the pins through respective holes in the PCB from a BGA surface of the PCB to an opposite surface of the PCB and engaging at least one pin with a threaded fastener on the opposite surface of the PCB.

20. The method of claim 14, wherein the pins face a BGA surface of the PCB, and the method comprises soldering the pins to the BGA surface.
